(19) United States
(12) Patent Application Publication
(10) Pub. No.: US 2016/0113105 A1
(43) Pub. Date: Apr. 21, 2016

(54) Vehicular Traffic Emergency and Safety Control System

(71) Applicants: Thomas Bach, Yorkville, IL (US); Charles Clifton, Roscoe, IL (US)

(72) Inventors: Thomas Bach, Yorkville, IL (US); Charles Clifton, Roscoe, IL (US)

(21) Appl. No.: 14/519,355

(22) Filed: Oct. 21, 2014

(51) Int. Cl. H05K 1/02; G08G 1/0967

(52) U.S. Cl. CPC H05K 1/028; G08G 1/0967

(57) ABSTRACT

The present invention discloses a vehicular traffic and safety control system that provides motorists with lane closure and other safety information in advance at a distance to allow motorists to anticipate traffic conditions at the site of a lane closure or changing traffic pattern. A portable large screen with LED lighting and messaging can be quickly set up to provide the necessary traffic information. The portable large screen is housed in a three to four foot long cylindrical casing that can be pulled out of a trunk, for example, and displayed quickly. The LED lighting, using current high visibility technology available, can provide important lane closure and other safety information at a distance to assist traffic more safely. Portability and visibility are important features of this invention.

### BACKGROUND OF THE INVENTION

1. Field of the Invention

This invention generally pertains to vehicular traffic control in situations where there is emergency activity, such as an accident on a road or highway, or associated lane closures as a result of an accident. Vehicular traffic control is also necessary at construction sites where safety is a major concern.

2. Description of the Prior Art

Vehicular accidents present safety issues for other vehicles arriving in the vicinity of the accident. Police departments have their own guidelines to safely secure the accident site while providing traffic routing or rerouting around the site. Commonly employed methods include the use of emergency lights to alert other drivers of the accident and to promote traffic flow around the site. One commonly used method of closing a lane to traffic is to place a squad car at an angle in the lane to be closed. Vehicles far enough away from the accident are aware of the accident activity, but may not be fully aware that one lane or more are closed until they encounter the squad car physically blocking the lane. This creates safety issues because of the bottleneck effect of the lane closure.

The same safety concerns are present at construction sites. Instead of using a squad car with flashing lights, often road control is done with people holding stop signs or other warning signs to slow and divert traffic around the construction site. The safety issues here are potentially more serious because of the high risk of personal injury that could result in a mishap at these sites. Once again, the vehicles are not necessarily aware of the exact routing around the site until they have a closer encounter with the traffic control person. In general, in any situation where traffic has to be rerouted or safely negotiated, there are the risks of property damage and personal injury.

The safety procedures and warning systems include the usual emergency lighting and various road signs, barriers and people directing traffic. Some of the warning systems are reflected in various patents issued over the years but all have shortcomings also. A U.S. Pat. No. 8,154,424, issued to Selevan describes modules that contain lights that are placed along a highway path to provide visibility as to the shape of the road. This is helpful at night to guide a path, but will not serve to close lanes or reroute traffic for any clear reason.

A U.S. Pat. No. 7,561,036, issued to Pederson describes a light bar powered by light emitting diodes (LEDs). It is intended to provide warning signals for emergency vehicles. It essentially duplicates the existing emergency lights.

A U.S. Pat. No. 6,963,275, issued to Smalls describes a portable warning light that warns that an object or car is stopped near the highway ahead. It does not serve to close lanes or reroute traffic.

A U.S. Pat. No. 6,683,532, issued to Peet II describes a folding portable light system. It contains a system of one or more articulated arrays of light blocks. Once again, it would not be helpful in lane closures or rerouting traffic.

A U.S. Pat. No. 5,103,205, issued to Halligan describes a traffic warning arrow with flashing lights. It is meant to mount on the trunk of a vehicle and uses the flashing warning circuit of the vehicle to enable the arrow to flash, thereby providing a warning to approaching vehicles from the rear. This device supplements the emergency lights currently in use.

A need exists for a traffic control system that alerts drivers of lane closures and routing changes well in advance of the actual location of the lane closures so that the drivers can anticipate their speed reduction and their expected change of lanes. This provides a safer and earlier lane change. By providing drivers with the opportunity to make decisions early, the actual point of lane change can take place with less confusion and greater safety. A traffic control system should be completely portable and easy to set up. The control system should be highly visible even in bright daylight. The control system should be able to be sized in accordance with the individual needs of the environment in which it is used. It should also provide communication of lane changes so that drivers know in advance of lane changes, rather than having to discover a lane change at the last moment. Further, a traffic control system should allow for a lane closure without placing a squad car in the closed lane, thereby reducing the risk of an accident. In construction areas, the risk of personal injury could also be reduced.

### SUMMARY OF THE INVENTION

An object of this invention is to provide a portable traffic control system that can be quickly deployed by emergency personnel at accident sites. Portability combined with visibility are the key features of this invention. In the preferred embodiment, this invention is cylindrical in shape and is approximately three to four feet long along the axis of the cylinder, and approximately six inches in diameter. The cylinder itself is actually a storage housing that stores a rolled up screen much like a standard house shade. A spring inside the housing rolls the screen into the housing in the same manner as a house shade. Pulling slightly on the screen releases a rachet mechanism that frees the screen to engage the spring force to fully retract the screen back into the cylindrical housing. In the retracted position, the housing is small enough to carry in a trunk of an emergency or construction vehicle.

A further object of the invention is to make deployment of the screen a quick operation. The cylindrical housing at the bottom end is inserted into a tube mounted vertically on the ground. The tube can be secured by inserting a metal spike through the tube's base into the ground, or a tube mounted on a metal base that can be held in position by rolling a vehicle's tire onto the metal base. The cylindrical housing at its bottom end would be approximately three feet above the ground level. The screen can then be pulled out of the housing to any desired length and be secured at that length with the internal ratchet. The edge of the screen furthest from the housing can then be secured with another tube mounted vertically on the ground in a similar manner. When fully deployed, the screen size is approximately three feet by twenty feet at its maximum.

A further object of the invention is to brightly display information that controls lane use or other information depending on the need at an accident site or construction site. The screen itself can be a plastic or nylon screen with square openings throughout such as seen in portable fences. The openings minimize the effect of the wind. Imbedded in the frame work of the screen are light emitting diodes (LEDs) arranged in a manner to provide information. An example would be a large arrow pointed in the direction of a lane change. Another would be a caution sign. Modern LEDs are very bright in daylight conditions and use very small currents and low voltages. This could allow the LEDs to be powered by a vehicles battery or cigarette outlet. Alternatively, a small battery, a power supply, or solar array can be the power source for the LEDs. A microprocessor controller can make the LEDs animate and change messages. For example, the LEDs can show a flashing arrow, or moving arrow, or be programmed to display different messages depending on the requirements at the scene.

A further object of the invention is to provide a wide versatility in its use to control traffic. Described above is a screen displayed as approximately three feet by twenty feet long. The height at the bottom of the screen is approximately three feet above the ground. The top of the screen is approximately six feet above the ground. A second cylindrical housing/screen combination can be placed on top of the first screen to give a total screen height (of the combination) of approximately nine feet. This provides greater visibility for a longer distance. With the increased number of LEDs now available with the two screens, more complicated messages can be sent, all controlled with the microprocessor controller. All possible power supply arrangements can power all the LEDs, whether with series or parallel connections for all power sources. Every cylindrical housing can have all the appropriate electrical connections needed for every possible combination of power sources. Further, every cylindrical housing/screen combination can be ganged together to cover a lot more ground than just a twenty foot width.

The screen itself is not just limited to plastic fence-like material. It can also be a solid sheet, such as plastic or canvas, with or without wind relief cuts in the sheet. There is no limit as to the material used. A solid sheet would provide the base for an extremely large number of LEDs to convey more detailed messages in an extremely bright format. The programming in the microprocessor controller could be extensive to present vivid lighting effects and messaging. There is no limit for the uses for this invention to provide bright visibility and portability for traffic control systems.

### BRIEF DESCRIPTION OF THE DRAWINGS

FIG. 1 shows the invention fully deployed.

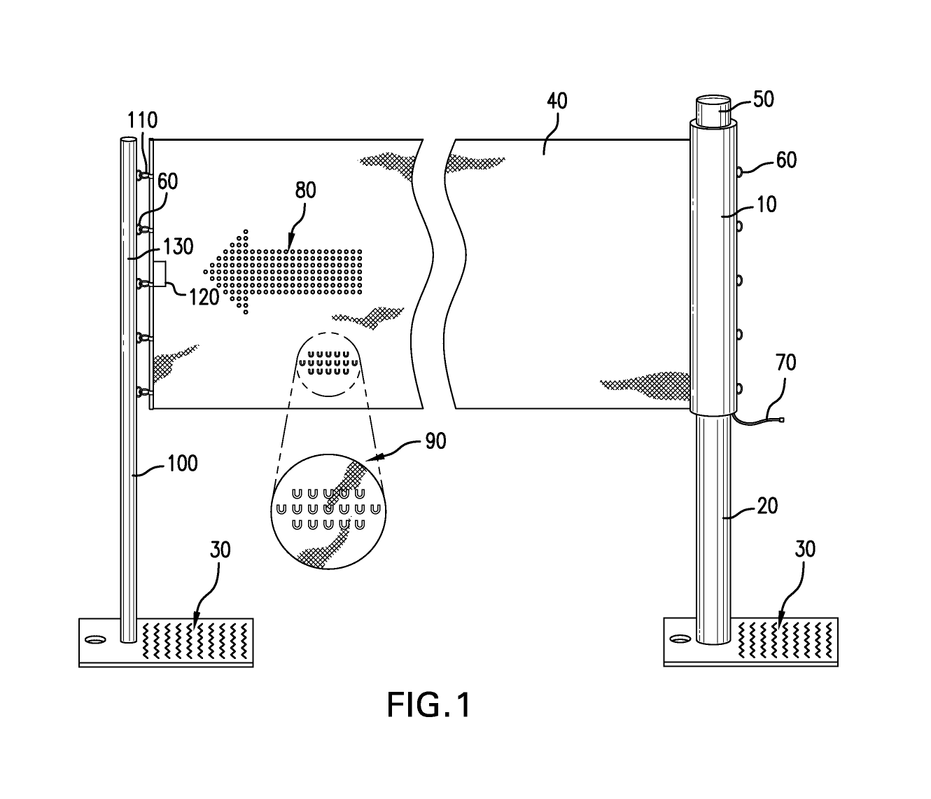

FIG. 2 shows the invention fully retracted on the right, and a mount pole extension on the left.

### DETAILED DESCRIPTION OF THE INVENTION

The current invention is a vehicular traffic emergency and safety control system having a cylindrical storage body 10. A recess in the bottom of cylindrical storage body 10 slides over mounting pole 20 to raise it to an appropriate height. Mounting pole 20 has mounting base 30 attached to it to provide a secure mounting to a ground surface. At the top of cylindrical storage body 10 is a mount stub 50 to allow a recess of a second cylindrical storage body 10 to be secured on top of the first cylindrical storage body 10. On the side of cylindrical storage body 10 is a plurality of closed ring clips 60. Screen 40 extends out of cylindrical storage body 10 to display bright LED lights 80. Power cord 70 allows for the power source for the LED lights 80. Magnification section 90 shows an enlarged detail of small wind relief cuts in screen 40 to reduce the effect of the wind on screen 40. Handle 120 conveniently allows screen 40 to be pulled out to its full length to attach to mount pole 100. Mount pole 100 is attached to mounting base 30. Screen 40 has spring clips 110 attached to it to secure the end of screen 40 to the closed ring clips 60 mounted on the side of mount pole 100. Cylindrical storage body 10 also has closed ring clips 60 on its side for additional screens 40 to attach to it.

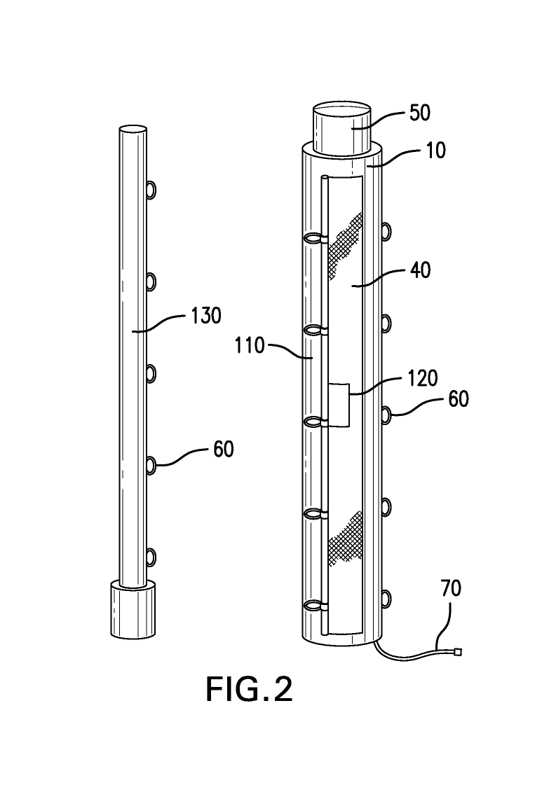

FIG. 2 shows cylindrical storage body 10 with screen 40 completely retracted into it. In addition. Mount pole extension 130 is shown with closed ring clips 60 attached to its side. The foregoing description of a preferred embodiment of the invention has been presented for purposes of illustration and description, and is not intended to be exhaustive or to limit the invention to the precise form disclosed. The description was selected to best explain the principles of the invention and practical application of these principles to enable others skilled in the art to best utilize the invention in various embodiments and various modifications as are suited to the particular use contemplated. It is intended that the scope of the invention not be limited by the specification, but be defined by the claims set forth below.

We claim:

1. A vehicular traffic and safety control system, comprising:
a. a portable flexible screen that extends from a cylindrical housing to display traffic information in an environment where safety and traffic control are required;
b. an LED array attached to the flexible screen to convey information about traffic and safety information;
c. a spool residing along the axis inside the cylindrical housing around which the flexible screen is wound and stored in the cylindrical housing;
d. a spring attached to the spool to assist in winding and storing the flexible screen into the cylindrical housing;
e. a ratchet assembly cooperating with the spring to allow the flexible screen to extend out to any length outside the cylindrical housing without winding back onto the spool;
f. an electrical connection wired from the LEDs and extending out of the cylindrical housing for a power source and a microprocessor as needed for programmed traffic and safety information;
g. a plurality of clips mounted at the extended edge of the flexible screen to secure the flexible sheet to an external mounting pole; and
H. a base at the bottom of the cylindrical housing to provide a secure mounting of the cylindrical housing to the ground with weights or stakes.

2. The vehicular traffic and safety control system as recited in claim 1, wherein the cylindrical housing has a mounting provision at the top to secure another cylindrical housing coaxially on top of it to display additional information at a greater height.

3. The vehicular traffic and safety control system as recited in claim 1, wherein the ratchet assembly cooperating with the spring has a release mechanism to allow the spring to rewind the flexible screen to its stored position inside the cylindrical housing.

4. The vehicular traffic and safety control system as recited in claim 1, wherein the external mounting pole has a plurality of corresponding clips to mount the flexible screen in its extended position.

5. The vehicular traffic and safety control system as recited in claim 4, wherein the external mounting pole is mounted to a base to secure the external mounting pole to the ground with weights or stakes.

6. The vehicular traffic and safety control system as recited in claim 1, wherein the external mounting pole has a mounting provision at the top to secure another mounting pole coaxially on top of it to secure another flexible screen with a plurality of corresponding clips.
